(19) United States
(12) Patent Application Publication
(10) Pub. No.: US 2025/0121321 A1
(43) Pub. Date: Apr. 17, 2025

(54) SYSTEM AND METHOD OF ABATING RESIDUAL EFFLUENT GASES

(71) Applicant: Applied Materials, Inc., Santa Clara, CA (US)

(72) Inventor: Ryan T. DOWNEY, San Jose, CA (US)

(21) Appl. No.: 18/912,465

(22) Filed: Oct. 10, 2024

Related U.S. Application Data
(60) Provisional application No. 63/600,418, filed on Nov. 17, 2023.
(60) Provisional application No. 63/544,926, filed on Oct. 19, 2023.
(60) Provisional application No. 63/543,847, filed on Oct. 12, 2023.

(51) Int. Cl. B01D 53/32; B01D 53/34; B01D 53/76; C23C 16/44

(52) U.S. Cl. CPC B01D 53/32; B01D 53/346; B01D 53/76; C23C 16/4412; B01D 2251/102; B01D 2258/0216; B01D 2259/818

(57) ABSTRACT

Disclosed herein are a system and a method for abating effluent gases output by a processing chamber. The abatement system includes a plasma source, a reagent delivery subsystem having a foreline, and a controller coupled with the processing chamber, the plasma source and the reagent delivery subsystem. The reagent delivery subsystem provides a first reagent gas into the foreline during a substrate processing period and includes a flow control device operable to regulate the flow rate of the first reagent gas. The controller controls the reagent delivery subsystem and the plasma source based on processing information of the processing chamber. During a chamber evacuation period of the processing chamber, the controller causes the reagent delivery subsystem to stop providing or reduce a flow rate of the first reagent gas while causing the plasma source to maintain the plasma.

### CROSS-REFERENCE TO RELATED APPLICATIONS

This application claims priority to the U.S. Provisional Patent Application Ser. No. 63/543,847 filed Oct. 12, 2023, the U.S. Provisional Patent Application Ser. No. 63/544,926 filed Oct. 19, 2023 and the U.S. Provisional Patent Application Ser. No. 63/600,418 filed Nov. 17, 2023, all of which are hereby incorporated herein by reference.

### BACKGROUND

### Field

The present disclosure generally relates to an abatement system and an abatement method for abating residual effluent gases. More particularly, embodiments of the present disclosure relate to abating residual effluent gases output by a processing chamber during a chamber evacuation period.

### Description of the Related Art

Effluent gases produced during semiconductor manufacturing processes include a variety of harmful compounds which need to be abated before disposal for regulatory compliance and environmental and safety concerns. To abate the effluent gases output by a processing chamber, reagent gases are continuously provided to an exhaust line that is coupled with the processing chamber for discharging the effluent gases. Sufficient reagent gases are provided to the exhaust line to ensure that the effluent gases are properly abated. When a processing of a substrate is completed, the processing chamber needs to be evacuated and get ready for the next operation. During this evacuation period, the processing chamber will have a much lower pressure, and the amount of effluent gases outputted the processing chamber will get reduced overtime. Due to the lower pressure in the processing chamber, the reagent gases in the foreline may flow into the processing chamber, causing undesirable problems.

Accordingly, there is a need to have an improved abatement system to continue abating effluent gases during a chamber evacuation period.

### SUMMARY

Disclosed herein are an abatement system and an abatement method for abating residual effluent gases output by a processing chamber. The abatement system includes a plasma source coupled with a first foreline and a second foreline. The first foreline is disposed upstream of the plasma source and configured to receive the effluent gases from the processing chamber. The second foreline is disposed downstream of the plasma source and coupled with a pump. The abatement system further includes a reagent delivery subsystem configured to provide one or more reagent gases into the first foreline and the second foreline and includes one or more flow control devices operable to regulate flow rates of the one or more reagent gases. The abatement system further includes a controller coupled with the processing chamber, the plasma source, and the reagent delivery subsystem. The controller is configured to control the reagent delivery subsystem and the plasma source based on processing information of the processing chamber. During a chamber evacuation period of the processing chamber, the controller causes the reagent delivery subsystem to stop providing or reduce a flow rate of at least one reagent gas to control the pressure of the forelines. Other reagent gases may be shut off or continue flowing depending on the pressure and the need to abate the residual gases. The plasma is maintained during the chamber evacuation period.

The abatement method of abating effluent gases of a processing chamber includes outputting effluent gases from the processing chamber to an abatement system disposed upstream of a pump; flowing one or more reagent gases into the forelines of the abatement system; and abating residual effluent gases output by the processing chamber during a chamber evacuation period. When abating the residual effluent gases, the abatement method regulates a pressure of the forelines such that a desired pressure level of the processing chamber may not be exceeded. The regulation of the pressure may include stopping the provision of reducing the flow rate of a reagent gas.

The present application also discloses a controller for controlling an abatement system for abating residual effluent gases output by a processing chamber. The controller includes a memory comprising computer-readable instructions; and a processor coupled to the memory, the processing chamber, a reagent delivery subsystem of the abatement system, and a plasma source of the abatement system. The computer-readable instructions, when read by the processor, cause the processor to receive processing information of the processing chamber and control the reagent delivery subsystem and the plasma source based on the processing information. During a chamber evacuation period, the processor is configured to cause the reagent delivery subsystem to stop flowing or reduce a flow rate of a first reagent gas and cause the plasma source to maintain a plasma.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic top view of a processing system, according to an embodiment of the present application.

FIG. 2 illustrates a schematic diagram of an abatement system, according to an embodiment of the present application.

FIG. 3 illustrates a detailed configuration of a pre-pump abatement system according to an embodiment.

FIG. 4 illustrates certain controlling operations implemented by the controller of the pre-pump abatement system according to an embodiment.

FIG. 5 illustrates certain controlling operations implemented by the controller of the pre-pump abatement system according to an embodiment.

FIGS. 6-13C illustrate additional examples of controlling operations that can be implemented by the controller of the pre-pump abatement system according to various embodiments.

FIG. 14 illustrates a method for abating residual effluent gases according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

Disclosed herein are an abatement system and an abatement method for abating residual effluent gases output by a processing chamber. During an evacuation period of the processing chamber, the pressure in the processing chamber is reduced to a much lower level because process gases are not provided. The abatement system, according to an embodiment, includes a plurality of flow control devices for each reagent gas. The abatement system independently controls the flow rates of each reagent gas. In one example, the control of the flow rates of each reagent gas may be based on processing information transmitted from the processing chamber, which may include a pressure of the processing chamber. The abatement system is capable of abating the residual effluent gases output by the processing chamber while maintaining the pressure in the abatement system below that of the processing chamber, thus preventing the reagent gases from flowing into the processing chamber. The abatement system advantageously control of the flow rates of each reagent gas in the period after substrate processing has been completed (i.e., an evacuation period), thus allowing residual exhaust gases to be treated while the processing chamber is being prepared for and/or during substrate transfer.

The abatement system may change the flow rates of selected reagent gases depending on the functions of each reagent gas during the evacuation period. For example, the abatement system may adjust or even stop the flow of a nitrogen gas into forelines because the nitrogen gas is in a less demand when the pressure in the foreline is lowered. The abatement system may also adjust or even stop the flow of water vapor because the amount of residual effluent gases in the forelines is reduced significantly. The abatement system may also stop or keep flowing the oxygen gas until the end of the evacuation period because the oxygen gas prevents the formation of particles in the forelines.

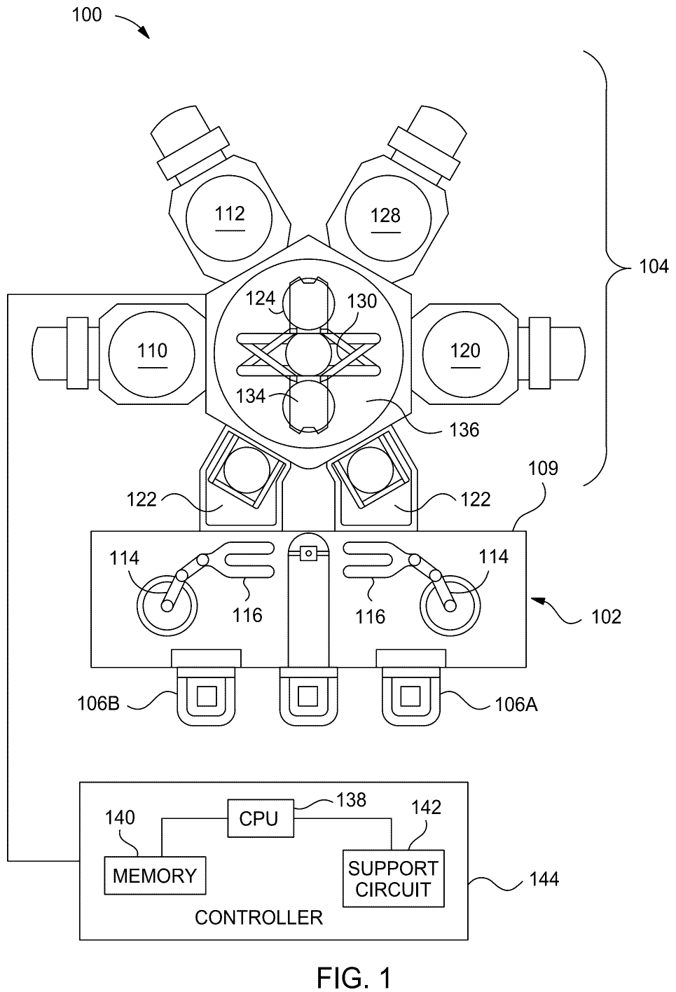

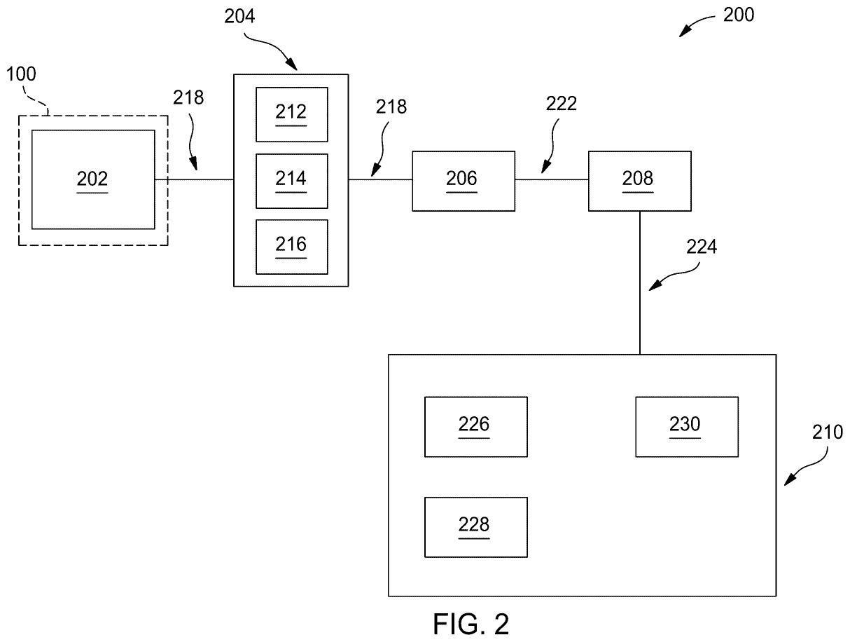

FIG. 1 illustrates a schematic top view of a processing system 100, according to one or more embodiments. The processing system 100 is coupled with an improved abatement system 200 (FIG. 2) as set forth in the present disclosure. The processing system 100 includes one or more load lock chambers 122 (two are shown in FIG. 1), a processing platform 104, a factory interface 102, and a controller 144. In one or more embodiments, the processing system 100 includes a CENTURA® integrated processing system, commercially available from Applied Materials, Inc., located in Santa Clara, California. It is contemplated that other processing systems (including those from other manufacturers) may be adapted to benefit from the disclosure.

The processing platform 104 includes a plurality of processing chambers 110, 112, 120, 128, the one or more load lock chambers 122, and a transfer chamber 136 that is coupled to the one or more load lock chamber 122. The transfer chamber 136 can be maintained under vacuum, or can be maintained at an ambient (e.g., atmospheric) pressure. Two load lock chambers 122 are shown in FIG. 1. The factory interface 102 is coupled to the transfer chamber 136 through the load lock chambers 122. According to an embodiment, one or more of the plurality of processing chambers 110, 112, 120, and 128 may be a low temperature EPI chamber, a plasma etch chamber, a chemical vapor deposition chamber, or other processing chamber. The processing chambers 110, 112, 120, and 128 generate effluent gases and output the effluent gases to an exhaust connected to an abatement system 200, which will be detailed below with reference to FIG. 2.

Continuing to refer to FIG. 1, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128. After a substrate processing is completed in a processing chamber 110, 112, 120, and 128, the processing gases in that processing chamber will be evacuated, which will be referred to as “a chamber evacuation period” in this application. The length of the chamber evacuation period may vary depending on the chamber and the exhaust system. In an example, a chamber evacuation period may last between 10 to 60 seconds, 10 to 40 seconds, or any other suitable length. Once the processing gases are emptied from the processing chamber, the one or more blades 134 will move into that processing chamber to transfer the processed substrate.

The controller 144 is coupled to the processing system 100 and is used to control processes. The controller 144 includes a central processing unit (CPU) 138, a memory 140 containing instructions, and support circuits 142 for the CPU. The controller 144 controls various items directly, or via other computers and/or controllers.

FIG. 2 illustrates a schematic diagram of an abatement system 200 coupled to the processing system 100 by a foreline 218, according to an embodiment. The foreline 218 is coupled at one end to the abatement system 200 and at the opposite end to the exhaust port of any one of the processing chambers 110, 112, 120, and 128 of the processing system 100, which is shown in FIG. 2 as a processing chamber 202. Processes that may be carried out in the processing chambers include a deposition process, an etch process, an annealing process, a cleaning process, or other semiconductor processes.

The foreline 218 serves as a conduit that routes effluent gases leaving the processing system 100 to the abatement system 200. Effluent gases may contain material which is undesirable for release into the atmosphere or may damage downstream equipment, such as vacuum pumps. For example, the effluent gases may contain compounds from a dielectric deposition process or from a metal deposition process. Examples of compounds present in the effluent gases include silicon-containing materials, chlorinated hydrocarbons (CHCs), hydrofluorocarbons (HFCs), chlorofluorocarbons (CFCs), or other compounds.

The abatement system 200 includes a pre-pump abatement system 204, a pump 206, an auxiliary abatement system 208, and a primary abatement unit 210. The foreline 218 couples the processing chamber 202 with the pre-pump abatement system 204 and is disposed upstream of the pre-pump abatement system 204. Another foreline 218 couples the pre-pump abatement system 204 with the pump 206 and is disposed downstream of the pre-pump abatement system 204. A transferring line 222 couples the pump 206 with an auxiliary abatement system 208. A transferring line 224 couples the auxiliary abatement system 208 with the primary abatement unit 210.

The pre-pump abatement system 204, as described in the present application, is capable of abating effluent gases both during a substrate processing period and a chamber evacuation period. The pre-pump abatement system may include a plasma source 214, a reagent delivery subsystem 212, and a controller 216. The plasma source 214 may be an in-line plasma source, or other suitable plasma source for generating a plasma within a treatment region of the pre-pump abatement system 204. The reagent delivery subsystem 212 delivers one or more reagents, such as abating reagents (which may be, for example, volatilizing or condensing abating reagents) into the foreline 218 or treatment region according to instructions by the controller 216. The reagent gases may include water, O₂, inert gas (N₂ and Ar), CH₄, H₂O, H₂, NF₃, SF₄, SF₆SF₈, F₂, HCl, HF, Cl₂, HBr, H₂, H₂O, Ar, O₃, CO, CO₂, NH₃, N₂O, CHₓF_{y}, CFₓ, BCl₃, CCl₄, SiCl₄, a reducing compounds, a halogenated etching compounds, or other suitable compounds. Nitrogen (N₂), argon (Ar), or clean dry air may be introduced into the forelines 218 for pressure control. The controller 216 is configured to control the reagent delivery subsystem and the plasma source according to the methods described herein (for example the operations of the methods as described in other parts of the present application). Similar with the controller 144, the controller 216 may include memories, supporting circuit, processors, and computer-readable instructions.

According to an embodiment of the present disclosure, the pre-pump abatement system 204 is configured to adjust the pressure in the foreline 218 to be no higher than the pressure of the processing chamber 202, thus preventing the reagent gases from flowing into the processing chamber 202. The pre-pump abatement system 204 is capable of selectively adjusting flow rates of reagent gases individually to lower the pressure of the foreline 218 while maintaining the plasma in the plasma source 214. Embodiments of the system and method as described in the present disclosure allow the residual effluent gases to be effectively abated during an evacuation period of the processing chamber 202.

The pump 206 is configured to draw the effluent gases from the pre-pump abatement system 204 to the auxiliary abatement system 208. The auxiliary abatement system 208 may include a compact scrubber. In some embodiments, the pump 206 may be a backing pump, such as a dry mechanical pump or the like. The pump 206 may have a variable pumping capacity with can be set at a desired level.

The auxiliary abatement system 208 is operable to treat the effluent gases before the effluent gases enter the primary unit 210. The auxiliary abatement system 208 is configured to treat certain water soluble gases, such as HF, HCL, or other gases. The auxiliary abatement system 208 functions as a compact unit, which does not occupy a substantial amount of physical space. The auxiliary abatement system 208 has moderate efficiency and reduces the burden on the primary abatement unit 210.

The primary abatement unit 210 is disposed downstream and coupled to the auxiliary abatement system 208. The primary abatement unit 210 is configured to treat exhaust gases from the processing chamber 202 in bulk. The primary abatement unit 210 includes a plurality of units for treating the effluent gases, including a water scrubber 226. In addition to a water scrubber 226, other abatement devices, such as a combustion unit 228 and a cooling unit 230, may be optionally included in the primary abatement unit 210.

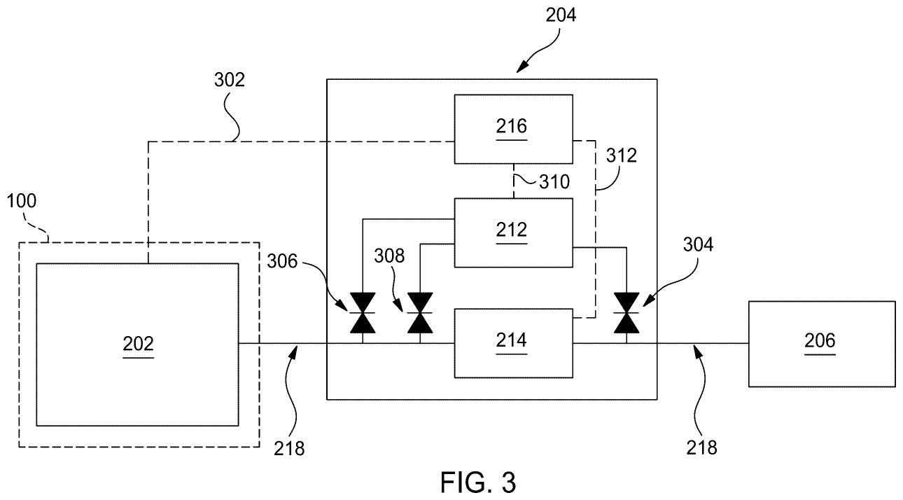

FIG. 3 illustrates a detailed configuration of the pre-pump abatement system 204 according to an embodiment. To control the flow rates of each reagent gas, a plurality of valves 304, 306, and 308 are disposed between the reagent delivery subsystem 212 and the foreline 218 to regulate the flow of the reagent gases. According to an embodiment, the valve 304 controls a reagent gas downstream of the plasma source 214, such as a nitrogen gas or other one of the reagent gases listed above. The valves 306 and 308 control reagent gases upstream of the plasma source 214, such as oxygen and water vapor, respectively. The valves 306 and 308 may control one of the other reagent gases as listed above. The valves 304, 306, and 308 can be any electrically controllable valves, such as solenoid flow valves or any other suitable flow control devices. Although FIG. 3 shows that the valves 304, 306, and 308 are disposed outside the delivery unit 212, the valves 304, 306, and 308 may be disposed inside the delivery unit 212 or be part of the delivery unit 212.

The controller 216 of the pre-pump abatement system 204 is coupled with the processing chamber 202, the reagent delivery subsystem 212, and the plasma source 214 via communication lines 302, 310, and 312, respectively. The controller 216 is configured to control operations of the reagent delivery subsystem 212 and the plasma source 214 based on processing parameters of the processing chamber 202. The processing parameters may include control command, pressure, temperature, flow rates, timing, gas type, and other process related information of the processing chamber 202.

During a substrate processing period, the controller 216, according to an embodiment, causes the plasma source 214 to maintain the plasma at a predetermined energy level. The controller 216 also causes the reagent delivery subsystem 212 to continuously provide one or more of the reagent gases at predetermined flow rates.

When a substrate processing is complete, the processing chamber 202 will enter into an evacuation period, during which the effluent gases in the processing chamber 202 will be evacuated. During the evacuation period, the processed substrate is removed from the processing chamber 202 and a new substrate is loaded into the processing chamber 202 for processing. The process gases may be stopped from flowing into the processing chamber or have a reduced flow rate during the evacuation period. As a vacuum pump of the processing chamber 202 continues pulling a vacuum from the processing chamber, the pressure of the processing chamber will be lowered. To continue abating the residual effluent gases output from the processing chamber during the evacuation period, the plasma source 214 keeps generating and maintaining the plasma. Alternatively, the plasma source 214 may intermittently maintain the plasma in the plasma source 214 during the evacuation period. According to an embodiment, the controller 216 causes the reagent delivery subsystem 212 to independently control the flow of each of the reagent gases into the foreline 218. For example, valves 304, 306, and 308 may be selectively adjusted to lower the pressure of the foreline 218 to a similar level as the pressure of the processing chamber 202. In another example, each of valves 304, 306, and 308 may raise, lower, pulse, cycle, turn on, turn off, or otherwise independently control the flow of each of the reagent gases provided to the foreline 218. The controller 216 may selectively control flow rates of one or more reagent gases based on a plurality of parameters, including the processing information of the processing chamber 202, functions of a reagent gas in the abating process, and any other suitable parameters. The flow rate of each of the reagent gases may be adjusted continuously or in discrete steps relative to the flow rate of each of the other reagent gases during the evacuation period.

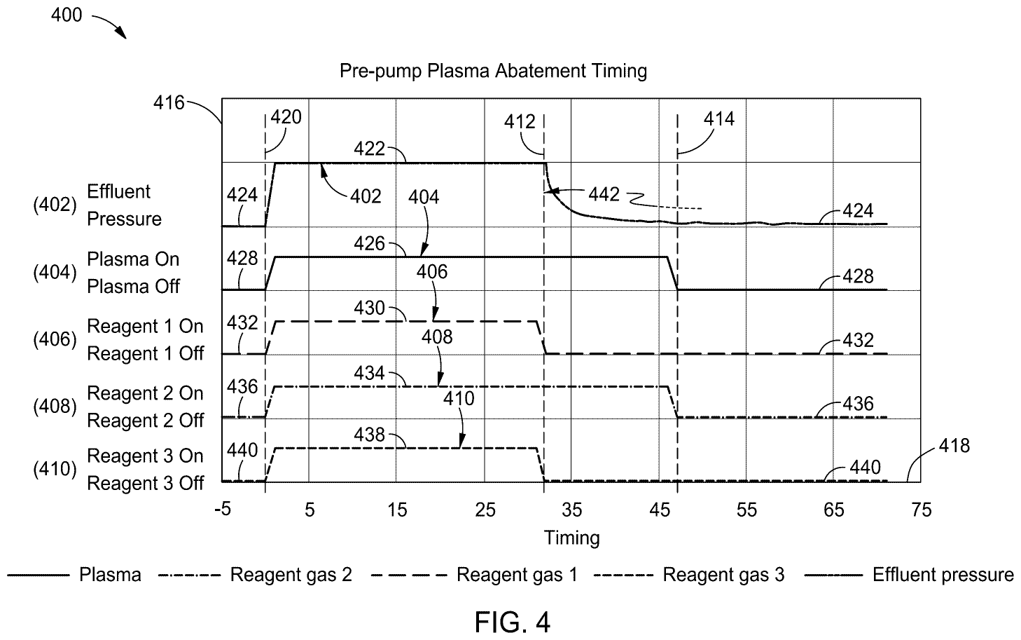

FIG. 4 illustrates certain controlling operations implemented by the controller 216 according to an embodiment. Timings of various operations are shown in a chart 400. The horizontal axis 418 of the chart 400 indicates time in seconds, while the vertical axis 416 of the chart 400 indicates the status of different events, including the generation of the effluent gases 402, the operation of the plasma source 404, the supply of Reagent 1 406, Reagent 2 408, and Reagent 3 410. A dash line 420 indicates the start of a substrate processing period. A dash line 412 indicates the end of a substrate processing period. The dash line 412 also indicates the start of a chamber evacuation period. The dash line 414 indicates an end of the abatement process for the residual effluent gases. At the timing corresponding to the dash line 414, the effluent gases output by the processing chamber 202 have been reduced to a negligible amount, such as 10%, 5%, or even smaller percentage of the effluent gases output during the substrate processing period.

The horizontal axis 418 approximately shows various timings of a processing cycle. The time indicated in the horizontal axis 418 is provided for illustration and should not be construed as a limitation. For example, at −5 second, the processing chamber is in a state of a very low pressure and is ready to receive process gases. At 0 second, the substrate processing period starts. Process gases are flowed into the processing chamber. As a result, the pressure of the effluent gases 402 rises from a low pressure level 424 to a stable level 422 in a short period of time, such as 2 seconds. At approximately 32 seconds, the substrate processing period ends, and the flows of processing gases are stopped or reduced. As a result, the pressure of the effluent gases 402 drops from the stable level 422 to the low pressure level 424. The complete pressure drop of the effluent gases 402 may take a relatively long period, such as 70 seconds shown in FIG. 4. But, most of the pressure drop occurs in an early period, such as approximately 15 seconds after the dash line 412. At the dash line 414, the abatement process for the residual effluent gases may end.

In the example shown in FIG. 4, the processing chamber 202 performs and etch process, an EPI deposition, or other process on a silicon based substrate that produces the effluent gases containing CHCs. Three reagent gases are illustrated in FIG. 4 as provided by the reagent delivery subsystem 212, although the reagent delivery subsystem 212 may be configured to provide more or less reagent gases. Three reagent gases may be any combination of the reagent gases disclosed above. In the example depicted in FIG. 4, the reagent gases include a water vapor (Reagent 1 in FIG. 4), an oxygen gas (Reagent 2 in FIG. 4), and a nitrogen gas (Reagent 3 in FIG. 3) are provided to abate the effluent gases in the foreline. It is to be understood that the selection of reagent gases is provide by way of example in FIG. 4, and other combinations or numbers of reagent gases may be alternatively utilized during the evacuation process as described herein. In the example depicted in FIG. 4, water vapor and the oxygen gas are provided to the foreline upstream of the plasma source 214, while the nitrogen gas is provided to the foreline downstream of the plasma source 214. Each reagent gas has a different role in the abatement process. For example, the nitrogen gas constitutes a majority of the total reagent gases and is provided into the foreline to improve the plasma generation and maintain the pressure in the foreline. The oxygen is provided into the foreline to prevent the formation of small particles. The water vapor functions as the main neutralizer that changes the CFC gases into less harmful and/or water soluble materials.

According to an embodiment, Reagent 1 404, the water vapor, can be adjusted between a fully on status 430 and fully off status 432; Reagent 2 406, the oxygen gas, can be adjusted between a fully on status 434 and a fully off status 436; and Reagent 3 410, the nitrogen gas, can be adjusted between a fully on status 438 and a fully off status 440. The plasma 404 can also be adjusted between a fully on status 426 and a fully off status 428. During the etch process (i.e., substrate processing in the processing chamber 202), the flow rates of the three reagent gases are typically flowed into the foreline at constant rates, and the plasma 404 is on.

As shown in FIG. 4, the etch process is conducted during a substrate processing period between dash lines 420 and 412. After the etch is completed, the effluent gases 402 in the processing chamber will be pumped out. Abatement is needed during the substrate processing period 422 between dash lines 420 and 412. Abatement is also needed during the chamber evacuation period 442 between dash lines 412 and 414 when the pressure of the effluent gases 402 gradually drops from the stable level 422 to the low pressure level 424.

According to an embodiment, the method to abate the residual effluent gas may turn off or otherwise adjust the supply of the nitrogen gas (Reagent 3 410) and the water vapor (Reagent 1 408) starting from the dash line 412, which indicates the end of the substrate processing period or the start of the chamber evacuation period. When the flow of the nitrogen gas and the water vapor is stopped, the pressure in the foreline can be effectively lowered to a level similar to the processing chamber, thus preventing the reagent gases from flowing into the processing chamber. In the meantime, the abatement method will maintain the flow rate of the oxygen gas (Reagent 2) and the plasma 404 in the foreline to continue abating the residual effluent gas.

According to an embodiment, the controller 216 (shown in FIG. 3) may gradually reduce or otherwise adjust the flow rate of the oxygen gas based on a pressure of the processing chamber. The controller 216 may also gradually reduce the flow rate of the nitrogen gas and the water vapor based on the pressure of the processing chamber. The flow of the oxygen gas and the plasma source can be turned off at the dash line 414.

Although the plasma 404 is shown as being maintained essentially throughout the entire evacuation period, the plasma 404 may be pulsed, cycled on/off or otherwise adjusted during the evacuation period. Similarly, the first and third reagents 408, 410 are shown as being turned off essentially throughout the entire evacuation period, flow of the first and third reagents 408, 410 may be pulsed, cycled on/off, ramped up, ramped down, or otherwise adjusted during the evacuation period.

FIG. 4 only illustrates operations related to abating residual effluent gases containing CFCs. When other types of effluent gases need to be abated, different reagent gases may be used. The method of the present disclosure contemplated that reagent gases may be turned off during the chamber evacuation period based on their functions. For example, an inert gas whose role is to maintain pressure and ensure a reliable plasma generation may be turned off first. Other reagent gases may be sequentially turned off depending on their abatement efficiency at lower pressure levels. Less efficient reagent gases may be turned off before reagent gases with higher efficiencies. Reagent gases whose function may become less critical at low pressure levels, such as water vapor, may also be turned off. Reagent gases which change the chemical characteristics of the effluent gases may be continuously provided to the abatement systems with or without a reduction of the flow rate.

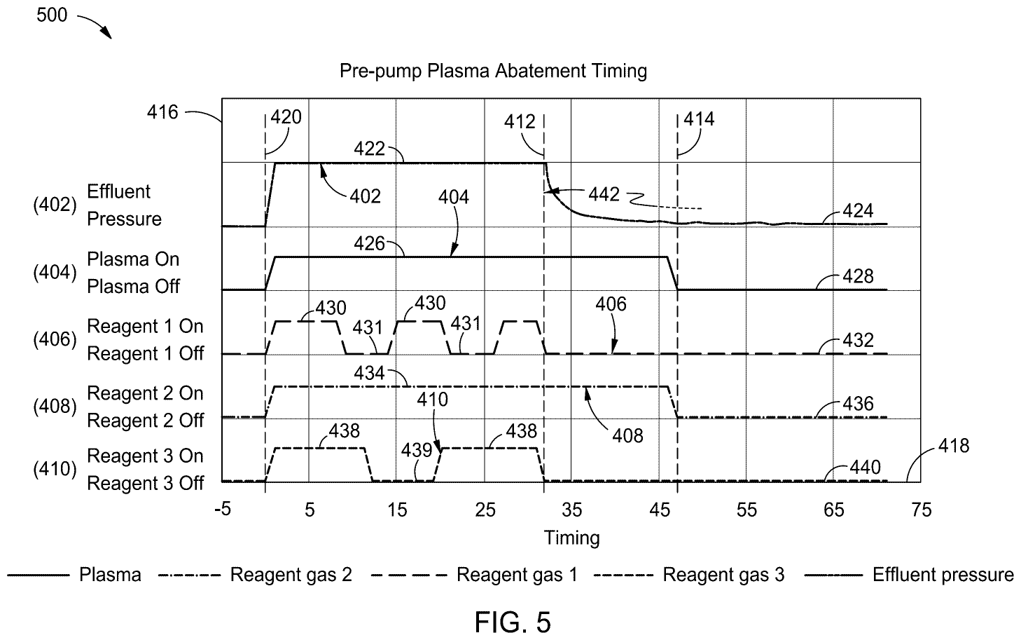

FIG. 5 illustrates certain controlling operations implemented by the controller 216 according to an embodiment depicted in a chart 500 of FIG. 5. Comparing to FIG. 4, Reagent 1 406 and Reagent 3 410, which are turned off at the beginning of the chamber evacuation period, may be intermittently supplied to the foreline during the substrate processing period between dash lines 420 and 412. For example, the reagent delivery subsystem 212 may stop the flow of Reagent 1 406, which is the water vapor, for a few intervals, such as two (2) periods 431. Each period 431 may be about five (5) seconds. According to an embodiment, the reagent delivery subsystem may stop the flow of Reagent 3 410, which is the nitrogen gas, for at least one period, such as one (1) period 439, which may be about five (5) seconds.

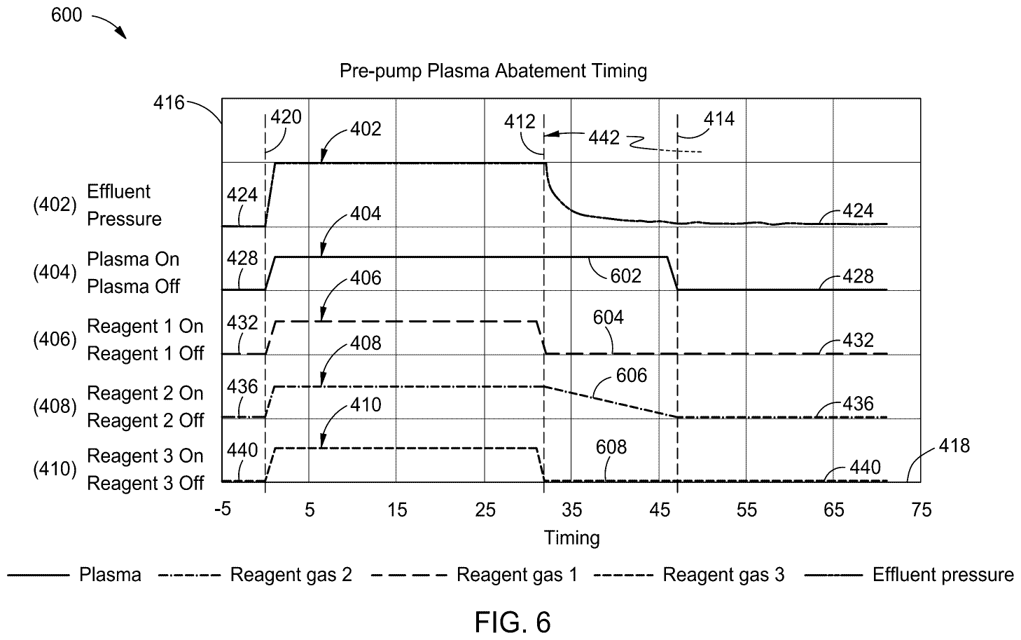

FIGS. 6-13C illustrate additional examples of controlling operations that can be implemented by the controller of the pre-pump abatement system according to various embodiments. The operations depicted in FIGS. 6-13C are similar to the operations described with reference to FIGS. 4-5, except for different examples for the independent control of reagent gases during the evacuation period. The examples of flow control of the reagent gases depicted in FIGS. 6-13C are not intended to be all inclusive, but rather provide additional context to how the flow reagent gases may be controlled during the evacuation period.

Referring first to the chart 600 illustrated in FIG. 6, the plasma 404 is maintained on during as illustrated by reference numeral 602 during the evacuation period; the first reagent 406, which may be any one or combination of the reagents described above, is turned off as illustrated by reference numeral 604 during the evacuation period; the flow of the second reagent 408, which may be any one or combination of the reagents described above, decreases in flow rate as illustrated by reference numeral 606 during the evacuation period; and the third reagent 410, which may be any one or combination of the reagents described above, is turned off as illustrated by reference numeral 610 during the evacuation period. Alternatively, the flow rates 604, 608 one or both of the first and third reagents 406, 410 may be ramped up, while the flow rate of the second reagent 408 is ramped up, turned off, or otherwise adjusted. Although the plasma 404 is shown as being maintained essentially throughout the entire evacuation period as illustrated by reference numeral 602, the plasma 404 may be pulsed, cycled on/off or otherwise adjusted during the evacuation period.

Alternatively, the flow of the first reagent 406 may be ramped down while the flow of the second reagent 408 is turned off, opposite to what is illustrated in FIG. 6.

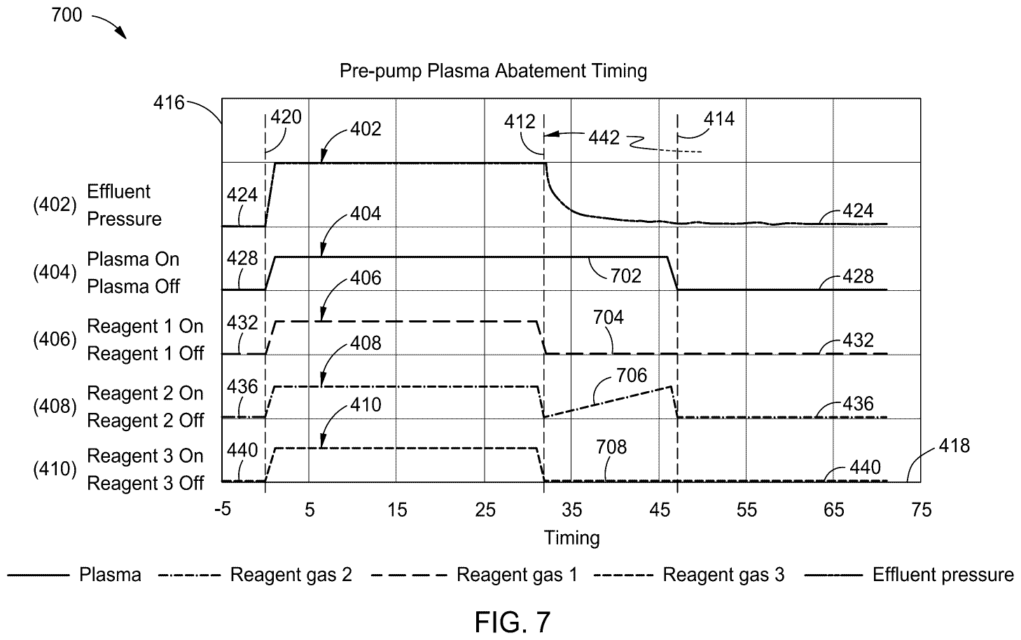

Referring first to the chart 700 illustrated in FIG. 7, the plasma 404 is maintained on during as illustrated by reference numeral 702 during the evacuation period; the first reagent 406, which may be any one or combination of the reagents described above, is turned off as illustrated by reference numeral 704 during the evacuation period; the second reagent 408, which may be any one or combination of the reagents described above, increases in flow rate as illustrated by reference numeral 706 during the evacuation period; and the third reagent 410, which may be any one or combination of the reagents described above, is turned off as illustrated by reference numeral 710 during the evacuation period. Alternatively, the flow rates 704, 708 one or both of the first and third reagents 406, 410 may be ramped up, while the flow rate of the second reagent 408 is ramped up, turned off, or otherwise adjusted. Although the plasma 404 is shown as being maintained essentially throughout the entire evacuation period as illustrated by reference numeral 702, the plasma 404 may be pulsed, cycled on/off or otherwise adjusted during the evacuation period.

Alternatively, the flow of the first reagent 406 may be ramped up while the flow of the second reagent 408 is turned off, opposite to what is illustrated in FIG. 7.

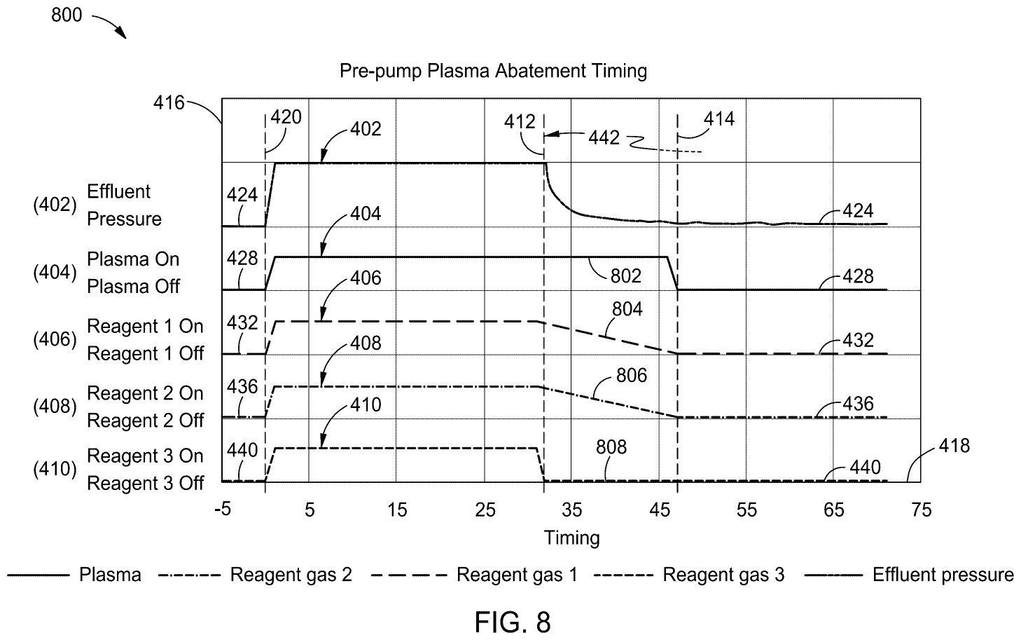

Referring next to the chart 800 illustrated in FIG. 8, the plasma 404 is maintained on during as illustrated by reference numeral 802 during the evacuation period; the flow of the first reagent 406, which may be any one or combination of the reagents described above, is ramped down as illustrated by reference numeral 804 during the evacuation period; the flow of the second reagent 408, which may be any one or combination of the reagents described above, is ramped down as illustrated by reference numeral 806 during the evacuation period; and the third reagent 410, which may be any one or combination of the reagents described above, is turned off as illustrated by reference numeral 808 during the evacuation period. Alternatively, the flow rate 808 of the third reagent 410 may also be ramped down, ramped up, turned off, pulsed, or otherwise adjusted. Although the plasma 404 is shown as being maintained essentially throughout the entire evacuation period as illustrated by reference numeral 802, the plasma 404 may be pulsed, cycled on/off or otherwise adjusted during the evacuation period.

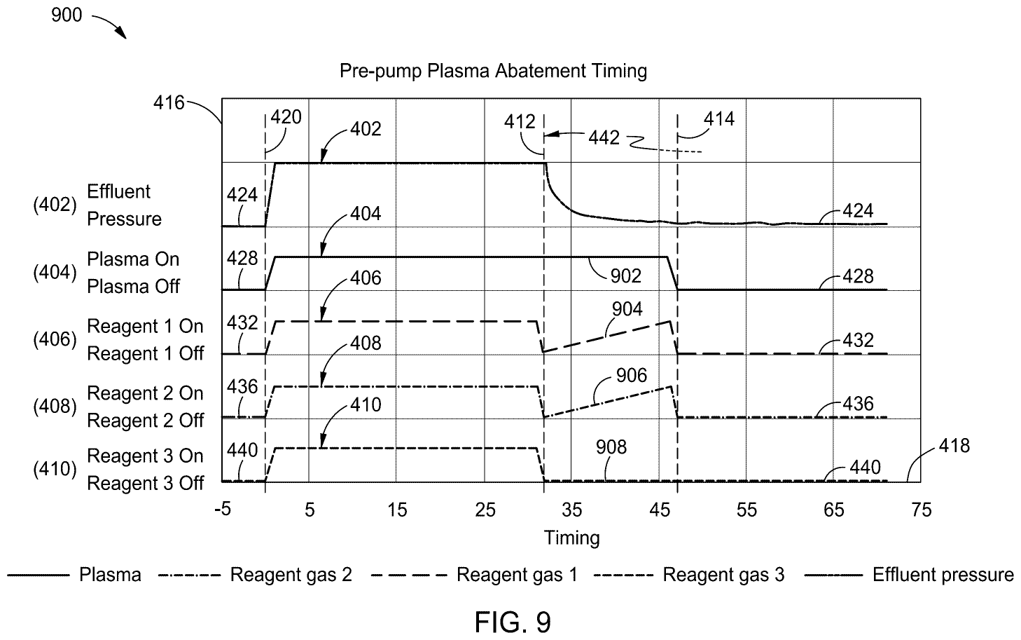

Referring next to the chart 900 illustrated in FIG. 9, the plasma 404 is maintained on during as illustrated by reference numeral 902 during the evacuation period; the flow of the first reagent 406, which may be any one or combination of the reagents described above, is ramped up as illustrated by reference numeral 904 during the evacuation period; the flow of the second reagent 408, which may be any one or combination of the reagents described above, is ramped up as illustrated by reference numeral 906 during the evacuation period; and the third reagent 410, which may be any one or combination of the reagents described above, is turned off as illustrated by reference numeral 908 during the evacuation period. Alternatively, the flow rate 908 of the third reagent 410 may also be ramped down, ramped up, turned off, pulsed, or otherwise adjusted. Although the plasma 404 is shown as being maintained essentially throughout the entire evacuation period as illustrated by reference numeral 902, the plasma 404 may be pulsed, cycled on/off or otherwise adjusted during the evacuation period.

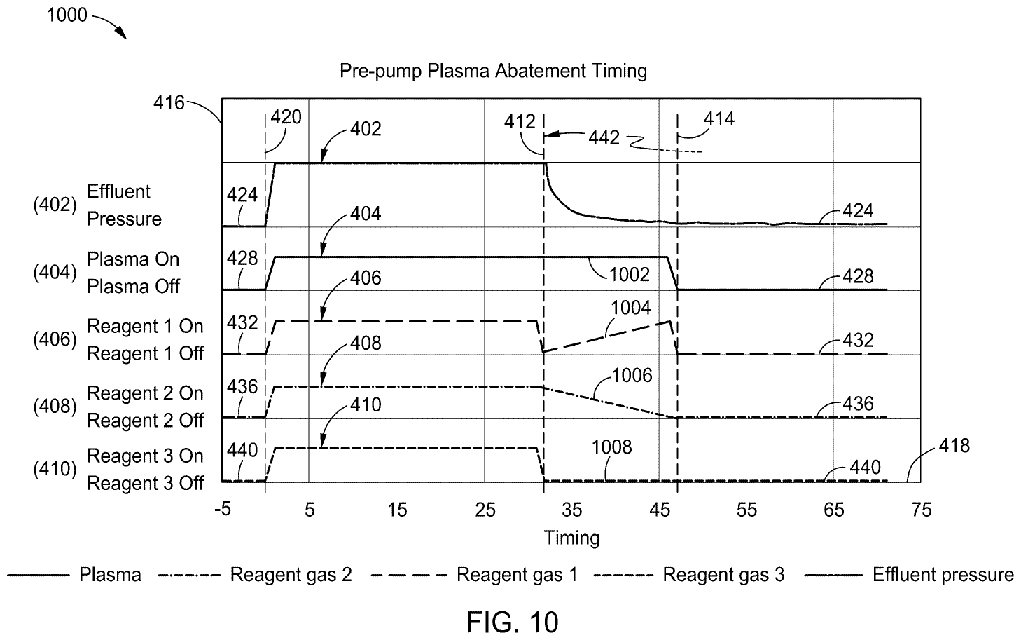

Referring next to the chart 1000 illustrated in FIG. 10, the plasma 404 is maintained on during as illustrated by reference numeral 1002 during the evacuation period; the flow of the first reagent 406, which may be any one or combination of the reagents described above, is ramped up as illustrated by reference numeral 1004 during the evacuation period; the flow of the second reagent 408, which may be any one or combination of the reagents described above, is ramped down as illustrated by reference numeral 1006 during the evacuation period; and the third reagent 410, which may be any one or combination of the reagents described above, is turned off as illustrated by reference numeral 1008 during the evacuation period. Alternatively, the flow of the first reagent 406 may be ramped down while the flow of the second reagent 408 is ramped up, opposite to what is illustrated in FIG. 10.

As discussed above, the flow rate 1008 of the third reagent 410 may also be ramped down, ramped up, turned off, pulsed, or otherwise adjusted. Although the plasma 404 is shown as being maintained essentially throughout the entire evacuation period as illustrated by reference numeral 1002, the plasma 404 may be pulsed, cycled on/off or otherwise adjusted during the evacuation period.

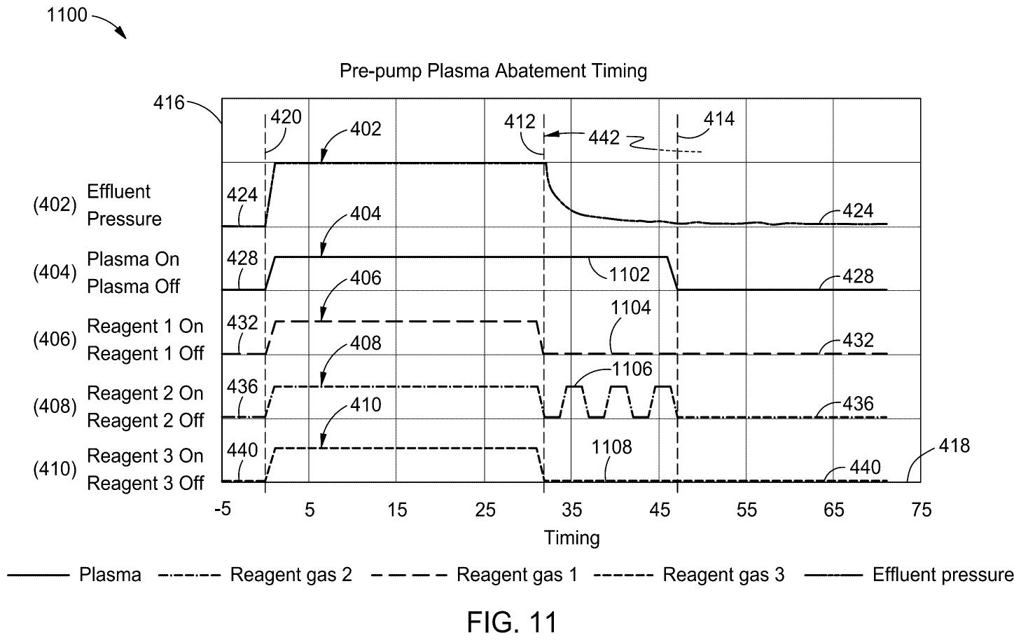

Referring next to the chart 1100 illustrated in FIG. 11, the plasma 404 is maintained on during as illustrated by reference numeral 1102 during the evacuation period; the flow of the first reagent 406, which may be any one or combination of the reagents described above, is turned off as illustrated by reference numeral 1104 during the evacuation period; the flow of the second reagent 408, which may be any one or combination of the reagents described above, is pulsed as illustrated by reference numeral 1106 during the evacuation period; and the third reagent 410, which may be any one or combination of the reagents described above, is turned off as illustrated by reference numeral 1108 during the evacuation period. Alternatively, the flow of the first reagent 406 may be pulsed while the flow of the second reagent 408 is turned off, opposite to what is illustrated in FIG. 11.

Alternatively, the flow of the second reagent 408 may be pulsed while the flow of the first reagent 406 is ramped down, ramped up, turned off, pulsed, or otherwise adjusted. Similarly, the flow of the first reagent 406 may be pulsed while the flow of the second reagent 408 is ramped down, ramped up, turned off, pulsed, or otherwise adjusted.

As discussed above, the flow rate 1108 of the third reagent 410 may also be ramped down, ramped up, turned off, pulsed, or otherwise adjusted. Although the plasma 404 is shown as being maintained essentially throughout the entire evacuation period as illustrated by reference numeral 1102, the plasma 404 may be pulsed, cycled on/off or otherwise adjusted during the evacuation period.

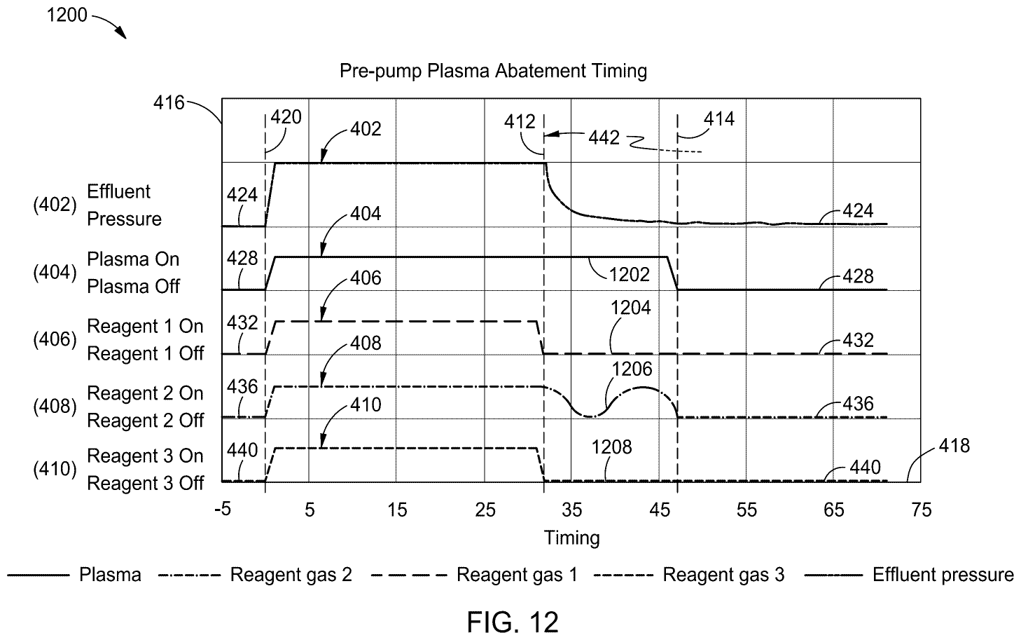

Referring next to the chart 1200 illustrated in FIG. 12, the plasma 404 is maintained on during as illustrated by reference numeral 1202 during the evacuation period; the flow of the first reagent 406, which may be any one or combination of the reagents described above, is turned off as illustrated by reference numeral 1204 during the evacuation period; the flow of the second reagent 408, which may be any one or combination of the reagents described above, is provided in a wave form, for example as a sine wave, as illustrated by reference numeral 1206 during the evacuation period; and the third reagent 410, which may be any one or combination of the reagents described above, is turned off as illustrated by reference numeral 1208 during the evacuation period. Alternatively, the flow of the first reagent 406 may be provided in a wave form while the flow of the second reagent 408 is turned off, opposite to what is illustrated in FIG. 12.

Alternatively, the flow of the second reagent 408 may be provided in a wave form while the flow of the first reagent 406 is ramped down, ramped up, turned off, pulsed, or otherwise adjusted. Similarly, the flow of the first reagent 406 may be provided in a wave form while the flow of the second reagent 408 is ramped down, ramped up, turned off, pulsed, or otherwise adjusted.

As discussed above, the flow rate 1208 of the third reagent 410 may also be ramped down, ramped up, turned off, pulsed, or otherwise adjusted. Although the plasma 404 is shown as being maintained essentially throughout the entire evacuation period as illustrated by reference numeral 1202, the plasma 404 may be pulsed, cycled on/off or otherwise adjusted during the evacuation period.

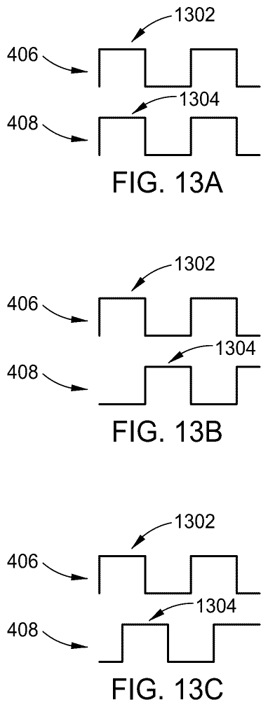

FIGS. 13A through 13C depict the phase variations between the two different reagent flows during the evacuation period. In FIGS. 13A through 13C, flows of the first and second reagents 406, 408 are shown by way of example. However, the flows representative of the flows of the first and third reagents 406, 410, and the flows of the second and third reagents 408, 410. Additionally, although the flows depicted in FIGS. 13A through 13C are shown as pulses, the different in phase between flows is also applicable to flows provided in a wave form, such as illustrated in FIG. 12.

Referring first to FIG. 13A, the “on” portions 1302, 1304 are the flows of the first and second reagents 406, 408 are shown as being in phase. That is, the flows of the first and second reagents 406, 408 are on during the same time.

In the example depicted in FIG. 13B, the “on” portions 1302, 1304 are the flows of the first and second reagents 406, 408 are shown as being out partially out of phase. That is, the flows of the first and second reagents 406, 408 are on during overlapping periods, but not completely during the same time.

In the example depicted in FIG. 13C, the “on” portions 1302, 1304 are the flows of the first and second reagents 406, 408 are shown as being 180 degrees out partially out of phase. That is, the flows of the first and second reagents 406, 408 are not on during overlapping periods.

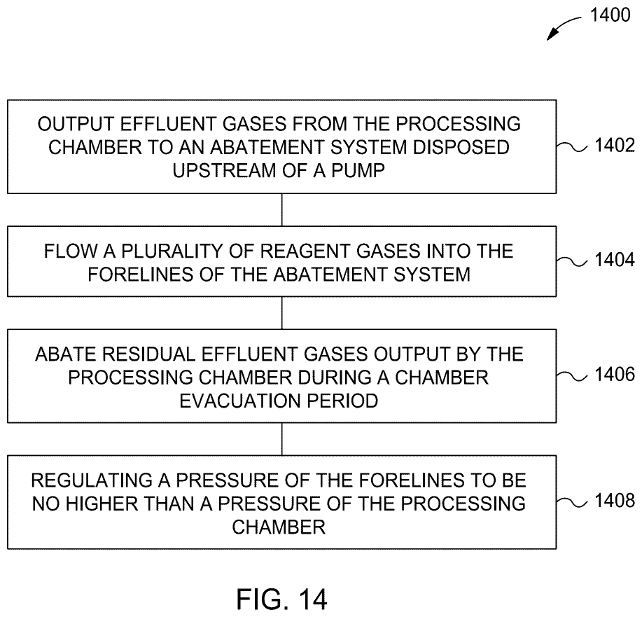

FIG. 14 illustrates a method 1400 for abating residual effluent gases according to an embodiment. The method 1400 includes an operation 1402 that outputs effluent gases from the processing chamber to an abatement system disposed upstream of a pump. The effluent gases are output to forelines of the abatement system during a substrate processing period and a chamber evacuation period. When effluent gases are output during the chamber evacuation period, the amount of the output effluent gases will be much less than the substrate processing period as processing gases are not flowing into the processing chamber. At operation 1404, a reagent delivery subsystem of the abatement system flows a plurality of reagent gases into the forelines of the abatement system during the evacuation period. The flows of each of the reagent gases provided during the evacuation period are independently controlled, for example but not limited by, the various examples disclosed above and the like. The plurality of reagent gases may be selected according to the processing chemistry of the processing chamber. In one embodiment, the plurality of reagent gases include water vapor, oxygen, nitrogen, or other ones or more of the reagent gases disclosed above and the like. At operation 1406, the abatement system abates the residual effluent gases output by the processing chamber during the chamber evacuation period. A plasma source of the abatement system maintains a plasma during the evacuation period. At operation 1408, when abating the residual effluent gases, the reagent delivery subsystem regulates a pressure of the forelines to be no higher than a pressure of the processing chamber. The method may include other operations for abating the residual effluent gases. For example, the method 1400 may shut off or otherwise adjust a flow control device of at least one reagent gas while continuing flowing at least one reagent gas into the forelines during the evacuation period. In one example, the method 1400 may shut off flow control devices of a nitrogen gas and water vapor while continuing flowing an oxygen gas into the forelines during the evacuation period. The method 1400 may receive processing information from the processing chamber, which may include the pressure of the processing chamber. The method may intermittently or otherwise flow the at least one reagent gas, such as nitrogen, into the forelines during a substrate processing period.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. An abatement system for abating residual effluent gases output by a processing chamber, the abatement system comprising:
a plasma source operable to generate a plasma and coupled with a foreline that flows the effluent gases;
a reagent delivery subsystem configured to provide a first reagent gas into the foreline; and
a controller coupled with the processing chamber, the plasma source and the reagent delivery subsystem, the controller configured to control the reagent delivery subsystem and the plasma source based on processing information of the processing chamber,
wherein during a substrate processing period, the controller causes the reagent delivery subsystem to provide the first reagent gas to the foreline while causing the plasma source to maintain the plasma; and during a chamber evacuation period of the processing chamber, the controller causes the reagent delivery subsystem to stop providing the first reagent gas or reduce a flow rate of the first reagent gas while causing the plasma source to maintain the plasma.

2. The abatement system of claim 1, wherein during the substrate processing period, the reagent delivery subsystem is configured to provide a second reagent gas to the foreline, and during the chamber evacuation period, the controller causes the reagent delivery subsystem to stop providing or reduce a flow rate of the second reagent gas.

3. The abatement system of claim 2, wherein during the substrate processing period, the reagent delivery subsystem is configured to provide a third reagent gas to the foreline, and during the chamber evacuation period, the controller causes the reagent delivery subsystem to continue providing the third reagent gas to the foreline.

4. The abatement system of claim 1, wherein the processing information comprises a pressure of the processing chamber.

5. The abatement system of claim 4, wherein the controller is configured to cause a pressure of the foreline to be no higher than the pressure of the processing chamber.

6. The abatement system of claim 2, wherein the first reagent gas comprises a nitrogen gas, and the second reagent gas comprises a water vapor, and wherein, during the chamber evacuation period, the controller is configured to stop flowing the nitrogen gas and the water vapor while an oxygen gas continues flowing into the foreline.

7. The abatement system of claim 6, wherein the controller is configured to shut off a flow control device for the oxygen gas when the plasma source is turned off.

8. The abatement system of claim 6, wherein, during the substrate processing period, the controller causes the nitrogen gas and the water vapor to be intermittently flowed into the foreline while the oxygen gas is being continuously flowed into the foreline.

9. A controller for controlling an abatement system for abating residual effluent gases output by a processing chamber, the controller comprising:
a memory comprising computer-readable instructions; and
a processor, wherein the computer-readable instructions, when executed by the processor, cause the processor to receive processing information of the processing chamber and control a reagent delivery subsystem and a plasma source based on the processing information, and
wherein during a substrate processing period, the processor is configured to cause the reagent delivery subsystem to provide a first reagent gas to a foreline of the abatement system while causing the plasma source to maintain a plasma, and during a chamber evacuation period, the processor is configured to cause the reagent delivery subsystem to stop providing or reduce a flow rate of the first reagent gas while causing the plasma source to maintain the plasma.

10. The controller of claim 9, wherein during the substrate processing period, the processor causes the reagent delivery subsystem to provide a second reagent gas to the foreline, and during the chamber evacuation period, the processing causes the reagent delivery subsystem to stop providing or reduce a flow rate of the second reagent gas to the foreline.

11. The controller of claim 10, wherein the processor causes the reagent delivery subsystem to continue flowing a third reagent gas during the chamber evacuation period.

12. The controller of claim 9, wherein the processor receives pressure information of the processing chamber.

13. The controller of claim 10, wherein the foreline couples the plasma source and the processing chamber, and the processor is configured to cause a pressure of the foreline to be no higher than a pressure of the processing chamber.

14. The controller of claim 9, wherein a water vapor, an oxygen gas, and a nitrogen gas are provided to the reagent delivery subsystem, and wherein, during the chamber evacuation period, the processor causes the reagent delivery subsystem to stop flowing the nitrogen gas and the water vapor while the oxygen gas continues flowing into the foreline.

15. The controller of claim 14, wherein, during the substrate processing period, the processor is configured to cause the nitrogen gas and the water vapor to be intermittently provided to the foreline while the oxygen gas is being continuously flowed into the foreline.

16. A method of abating effluent gases of a processing chamber, the method comprising:
outputting effluent gases from the processing chamber to an abatement system disposed upstream of a pump;
flowing a first reagent gas into a foreline of the abatement system during a substrate processing period; and
abating residual effluent gases output by the processing chamber during a chamber evacuation period,
wherein abating the residual effluent gases comprises regulating a pressure of the foreline to be no higher than a pressure of the processing chamber.

17. The method of claim 16, wherein abating the residual effluent gases further comprises:
shutting off a flow control device of the first reagent gas while continuing flowing at least another reagent gas into the foreline.

18. The method of claim 17, wherein abating the residual effluent gases further comprising:
shutting off flow control devices of a nitrogen gas and water vapor while continuing flowing an oxygen gas into the foreline.

19. The method of claim 17, further comprising:
receiving processing information of the processing chamber, the processing information comprising the pressure of the processing chamber.

20. The method of claim 17, further comprising:
intermittently flowing the first reagent gas into the foreline during a substrate processing period.
